(19) United States
(12) Patent Application Publication
(10) Pub. No.: US 2018/0323091 A1
(43) Pub. Date: Nov. 8, 2018

(54) METHOD AND APPARATUS FOR UNIFORM THERMAL DISTRIBUTION IN A MICROWAVE CAVITY DURING SEMICONDUCTOR PROCESSING

(71) Applicant: APPLIED MATERIALS, INC., Santa Clara, CA (US)

(72) Inventors: Preetham Rao, Singapore (SG); Dennis Ivanov, St. Petersburg (RU); Ananthkrishna Jupudi, Singapore (SG); Yueh Sheng Ow, Singapore (SG)

(21) Appl. No.: 15/966,211

(22) Filed: Apr. 30, 2018

Related U.S. Application Data
(60) Provisional application No. 62/500,609, filed on May 3, 2017.

(51) Int. Cl. H01L 21/67; H05B 6/64; H05B 6/66; H05B 6/70

(52) U.S. Cl. CPC H01L 21/67115; H05B 6/6402; H05B 6/707; H05B 6/705; H05B 6/664

(57) ABSTRACT

Methods and apparatus for uniform thermal distribution across semiconductor batches are provided herein. According to one embodiment, a microwave oven for semiconductor processing, comprising a thermal housing having a cavity and a plurality of input ports, a power source configured to provide a microwave signal to the cavity of the thermal housing via the plurality of input ports, a phase shifter disposed between the power source and the input ports, wherein the phase shifter is configured to vary a phase difference between two or more signals provided to it; and a controller communicatively coupled to the phase shifter and configured to control the phase difference between the two or more signals.

### CROSS-REFERENCE TO RELATED APPLICATIONS

This application claims benefit of U.S. provisional patent application Ser. No. 62/500,609, filed May 3, 2017, which is herein incorporated by reference in its entirety.

### FIELD

Embodiments of the present disclosure generally relate to semiconductor wafer level packaging.

### BACKGROUND

Microwave ovens are widely used for several industrial applications including semiconductor wafer level packaging, where a batch of wafers is typically heated. Uniformly heating all wafers in the batch is important in obtaining the highest quality of curing or moisture removal. The inventors have discovered that in addition to an effective design of the oven to achieve uniform heating, control mechanisms can advantageously be used to vary the spatial heating pattern in the oven.

Therefore, the inventors have developed methods and apparatus for uniformly heating a plurality of substrates in a batch heating process.

### SUMMARY

Methods and apparatus for uniform thermal distribution across semiconductor batches are provided herein. According to some embodiments, a microwave oven for semiconductor processing may include a thermal housing having a cavity and a plurality of input ports, a power source configured to provide a microwave signal to the cavity of the thermal housing via the plurality of input ports, a phase shifter disposed between the power source and the input ports, wherein the phase shifter is configured to vary a phase difference between two or more signals provided to it; and a controller communicatively coupled to the phase shifter and configured to control the phase difference between the two or more signals.

According to another embodiment, a method for processing a substrate includes providing a plurality of microwave signals to a substrate disposed in a microwave cavity to treat the substrate, controlling a phase of at least one of the plurality of microwave signals to be different than at least one other of the plurality of microwave signal, and measuring control parameters of the substrate and the microwave cavity, and controlling the phase based on the control parameters.

According to some embodiments, a microwave oven for uniformly heating semiconductor wafers may include a thermal housing with a cavity where the semiconductor wafers are suspended, a phase shifter, coupled to the thermal housing that introduces a phase difference of approximately 0 degrees to 180 degrees between two or more signals, a power source coupled to the phase shifter that generates a power signal, and a controller that varies a phase difference between the two or more signals based upon properties of the semiconductor wafers.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a block diagram of an apparatus for uniform thermal distribution in a cavity in accordance with at least some embodiments of the present disclosure.

FIG. 2 is a diagram illustrating the function of the apparatus in FIG. 1 in accordance with at least some embodiments of the present disclosure.

FIG. 3 is an illustration of electric field distribution at various phases across a semiconductor wafer in accordance with at least some embodiments of the present disclosure.

FIG. 4 is a block diagram of a controller in accordance with at least some embodiments of the present disclosure.

FIG. 5 is a method for uniform thermal distribution in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a method and apparatus for uniformly heating semiconductor batches in a cavity are provided herein. Some semiconductor wafers have an epoxy base, with working silicon dies embedded in the epoxy. In some instances, these dies can be logic chips, memory chips, signal processing chips, or the like. Metal contacts are built upon these chips forming external connections. The wafer also goes through several other production steps such as depositing a passivation layer, a polymer layer and a metal redistribution layer. Then, solder bumps are created for external connections. Generally, these wafers are referred to “fan-out wafers” and the production process is referred to as “fan-out wafer level packaging”.

During the production process, degassing and curing of the epoxy wafers is performed in microwave ovens to remove moisture from the wafers in order to proceed to metallization and sputtering to avoid outgassing during these processes. Further, due to the differing geometries of various wafers that may be cured using the same apparatus, the heating across the wafers will differ. Thus the inventors have created methods and apparatus that can be used during various phases of fan-out wafer-level packaging to improve degasing and curing via uniform thermal distribution and electric field exposure.

More specifically, microwave ovens heat the objects inside using the principle of standing waves. The standing waves correspond to resonant frequencies of a given shape and size of the cavity. In embodiments of the present disclosure, the operating frequencies of a microwave oven are chosen to maximize the number of resonant modes, so that the field distribution, and hence the heating pattern is uniform within the heated object. Power that is fed to the microwave oven cavity in high power industrial applications is often through multiple input sources. In wafer level packaging, variable frequency microwave power supply is used, to achieve a high degree of thermal uniformity, as well as to prevent arcing inside the oven cavity due to the presence of metal components. The design of variable frequency microwave oven cavity is non-trivial and involves the identification of resonant frequencies of the cavity which can be geometrically complex, along with wafers whose epoxy and metal composition can vary significantly. Computing the resonant modes among a wide band of frequencies involves solving Maxwell equations governing the electro-magnetic field distribution using complex and time consuming computer based models. Hence many times a design is non-optimal and involves a high number of non-resonant frequency components resulting in non-uniform field distribution in the cavity. Thus, embodiments of the present disclosure advantageously provide control mechanisms on the input feeds in such a case to adjust the field uniformity. More specifically, by introducing a phase difference in the input feeds, control can be achieved. The variation of phase difference between inputs causes the microwave fields from each launch within the oven to constructively or destructively interfere. This causes a variation in the field pattern and hence the resonant modes. This effect is similar to altering the shape or size of the oven cavity slightly to change the field distribution.

Furthermore, changing the phase difference converts resonant modes to evanescent modes and vice versa as described below in more detail. This introduces more previously non-existent resonant modes in the same frequency band of the variable frequency drive. This essentially equals to having a mode stirrer, or a wafer stack rotator or a vertical oscillatory drive. This is extremely beneficial to achieving high degree of uniformity in the field. Exact frequency modes can advantageously be chosen to concentrate the field in certain areas of the load by shifting phase in order to control the heating as desired.

At least some embodiments consistent with the present disclosure consist of a multisource microwave cavity, power source(s), wave guides and a phase shifter for a dual source microwave oven, as shown in the figures and described in more detail below.

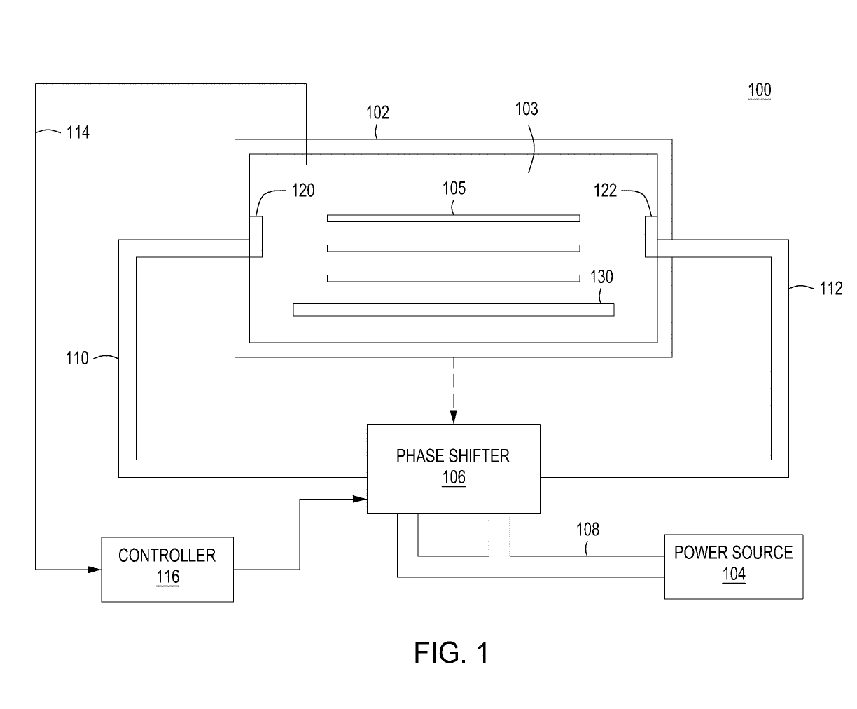

The apparatus 100 described in FIG. 1 is used during polymer coating and patterning on the epoxy wafer to uniformly distribute the electric field in a cavity for curing the polymer uniformly. Later, when the copper lines are built up (e.g., damascene structures), the wafer is placed in the apparatus 100 for moisture removal to ensure dry copper.

According to one embodiment disclosed by the inventors, an apparatus for curing and moisture removal from a semiconductor wafer is coupled to a phase shifter which controls a phase difference between microwave power input feeds to the apparatus. Each feed of microwave signals has a different phase and the phase difference between the microwave signals is controlled and varied according to properties of the wafer, causing the electromagnetic fields of the microwave signal feeds to construct and deconstruct with each other, creating various modes of electric field distortion, randomizing field intensity and introducing uniformity of heating in the cavity.

FIG. 1 is a block diagram of an apparatus 100 for uniform thermal distribution in a cavity in accordance with embodiments presented herein.

The apparatus 100 (e.g., a microwave oven) comprises a thermal housing 102 with a cavity 103 where objects 105 are placed for heating and curing, for example. In some instances, objects 105 are batches of semiconductor wafers undergoing the curing and moisture removal phases of packaging. The apparatus 100 further comprises a first input port 120 and a second input port 122. In some embodiments, the apparatus 100 comprises more input ports, depending on the number of input power sources provided by phase shifter 106.

The apparatus 100 further comprises a power source 104, which in some instances may be an amplifier or the like. The power source 104 is a variable frequency power source, generally operable for higher power industrial applications. The power source 104 is, in some embodiments, a variable frequency microwave drive (VFMD). For example, some configurations allow the power source 104 to vary across 4096 frequencies, each for approximately 25 seconds. A VFMD reduces the possibility of arcing that may occur in metal components of the apparatus 100 and maintains some level of uniformity of temperature within cavity 103 by mingling different patterns of heating to attempt to obtain uniform heating on all wafers being processed, however small variations can still occur due to the compactness of the apparatus 100 and the material properties of epoxy silicon and dies, leading to unpredictable uniformity. Thus, a phase shift is introduced via a phase shifter 106 to obtain stable uniformity across the wafers.

The power source 104 is coupled via a waveguide 108 to the phase shifter 106. The waveguide 108 splits the incoming signal from the power source 104, providing at least two signals to the phase shifter 106. In some embodiments the at least two microwave signals are equal in amplitude and frequency. In some embodiments the at least two microwave signals differ in amplitude and frequency. In some embodiments, the waveguide 108 splits the signal into more than two signals. The phase shifter 106 controls a phase difference between the two or more microwave signals by shifting the phase of at least one of the microwave signals while maintaining the phase of at least one of the other signals.

In some embodiments, the phase shifter 106 can be embedded in the feed waveguide of one of the sources. In other embodiments of the disclosure, a digital phase shifter can be embedded prior to the feed to waveguide supplying to one of the sources. In some embodiments, the phase shifter 106 contains a knob or other controller to vary the phase difference between the input and the output. This can be a physically rotating knob, a digital control circuitry, or the like.

The length of the waveguides 108, and the location of the phase shifter 106 is selected such that the default phase difference between the input sources is known to sufficiently accuracy. For example, in some embodiments, the difference between the waveguide lengths without the phase shifter is selected to be an integral multiple of the average wavelength of the input microwave power supply so that the waves entering the domain from multiple sources are in phase.

In the example depicted in FIG. 1, the phase shifter 106 splits the microwave signal from power source 104 into two microwave signals. The first signal travels along waveguide 110 with, for example, no phase shift introduced, while the second signal travels along waveguide 112 with, for example, a 90 degree phase shift from the original power signal. The second signal consequently has a 90 degree phase difference as compared to the first signal. In some embodiments, the phase difference between input sources is 90 degrees, while in other embodiments the phase difference introduced by the phase shifter 106 is varied by the controller 116 anywhere between zero degrees to 180 degrees by mechanical, electrical or digital adjustment of controls of the phase shifter 106.

As each signal travels through the respective waveguide 110 and 112, the signals enter the cavity via respective ports 120 and 122 at approximately the same time at opposing ends of the cavity 103. The electric field of the two signals constructively and destructively interfere, resulting in a variation in the electric field pattern and resonance modes across the objects 105, thus advantageously providing a more uniform heating of, for example, wafer(s) being processed.

According to some embodiments, a feedback mechanism 114 is provided to convey the control parameters of the cavity 103 and/or the objects 105 within the cavity 103, back to the phase shifter 106 directly, or via an intermediary such as controller 116. In some instances, the controller 116 measures the control parameters. The controller 116 modifies the phase difference between the signals introduced by the phase shifter 106 according to the received properties. Examples of some control parameters comprise temperature of the cavity 103, temperature of the objects 105 in the cavity 103, geometry of the cavity 103, moisture levels detected on the objects 105 or within the cavity 103, direct electromagnetic field measurements of the object 105 or the cavity 103, or other readings related to the objects. Depending on the temperature uniformity of the wafers being processed, the phase difference between input sources can be adjusted using a stepper motor or solenoid (for example) that controls a knob of the phase shifter 106 or an external voltage supplied to the phase shifter 106. Other means of controlling the phase difference are also contemplated by the present disclosure such as the controller 116 directly modifying the phase of at least one of the input signals via a digital signal from the controller 116 to the phase shifter 106.

In order to achieve optimal and effective curing/moisture removal of the object (e.g., semiconductor), the object being processed by apparatus 100 is exposed to a varied spatial heating pattern in cavity 103. According to the inventors, the electromagnetic field and thermal variation across the object surface created by the phase differing signal sources provides relatively uniform thermal distribution to the object resulting in more uniform curing and moisture removal as compared to conventional curing/moisture removal processes. Further, the controller 116 may change modes from non-resonant to evanescent, creating a mixture of modes and randomizing electric field intensity leading to more uniform curing than conventional methods.

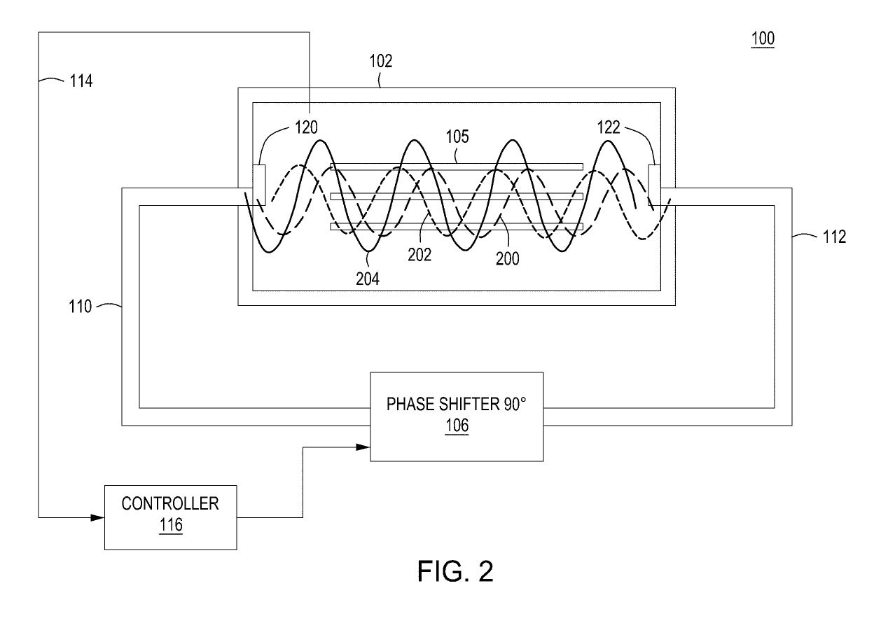

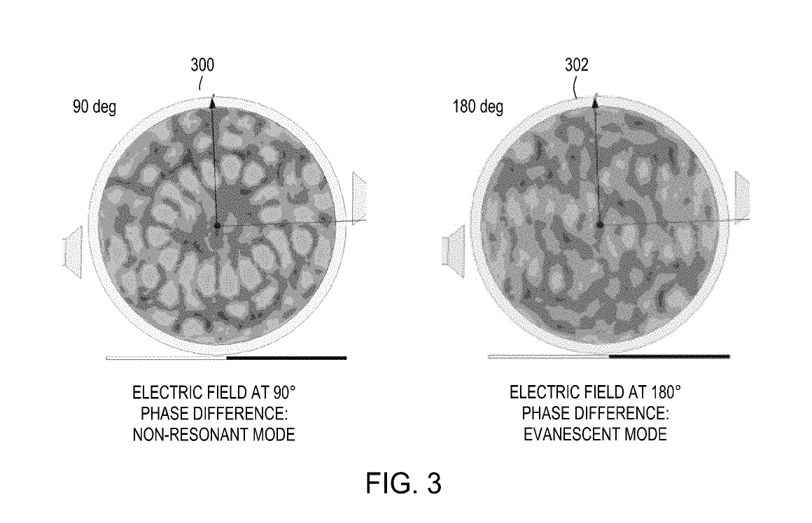

As shown in FIG. 2, the port 120 generates microwave signal 200 and port 122 generates microwave signal 202. Those of ordinary skill in the art will recognize that the signals illustrated are only representative of microwave power and the physical signals introduced by ports 120 and 122 may differ significantly. The illustrated microwave signals 200 and 202 constructively and destructively interfere forming a microwave 204. The microwave 204 has deeper peaks and valleys, resulting in an electric field pattern as illustrated in FIG. 3, image 300. Image 300 illustrates what is referred to as “non-resonant mode”.

The controller 116 may adjust the phase difference to 180 degrees after the phase difference was 90 degrees for a period of time. Image 302 of FIG. 3 illustrates the electric field pattern witnessed when a 180 degree phase difference is created between the wave input by port 120 and the wave input by port 122, referred to as “evanescent mode”.

By varying the phase difference introduced by the phase shifter 106 across the described range, uniform heating of the objects 105 being processed is achieved. In some embodiments, the apparatus 100 is used for curing and moisture removal, and can be used during degasing of epoxy wafers, copper annealing, smoothening or any process which can benefit from uniform electromagnetic distribution.

According to another embodiment, the controller 116 adjusts the physical position of the object 105 within cavity 103 via optional pedestal 130 in order to modify the position of the object 105. In other embodiments, the pedestal 130 provides radiant heating to the object 105 in addition to microwave heating. The controller 116 adjusts the height of the pedestal 130, or the positioning of the pedestal 130 in other dimensions via mechanical means based on the control parameters measured in the apparatus 100. The repositioning of pedestal 130 is complimentary to the phase shifting of the phase shifter 106 and in some instances the position of pedestal 130 remains static.

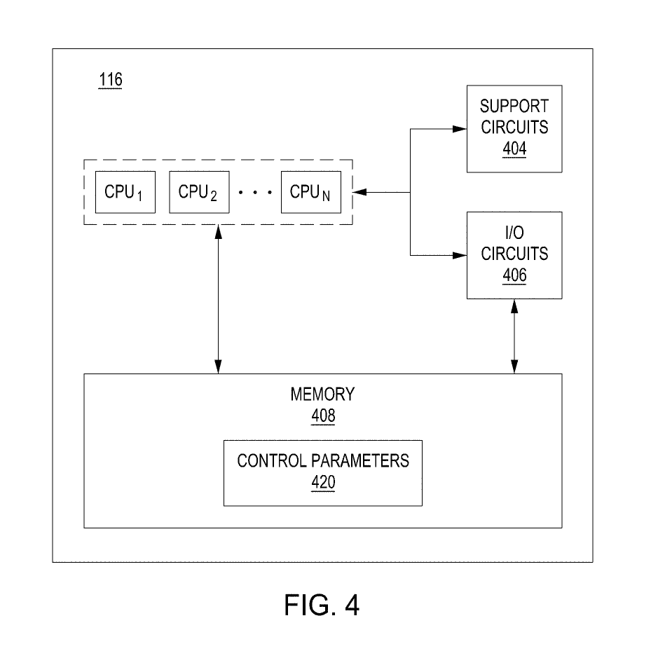

FIG. 4 is a block diagram of a controller 116 in accordance with exemplary embodiments of the present disclosure.

Various embodiments of methods for controlling a phase shifter may be executed by the controller 116. FIG. 4 is just an exemplary embodiment of controller 116, while other configurations and embodiments are possible. According to the embodiment depicted in FIG. 4, the controller 116 comprises one or more CPUS 1 to N, support circuits 404, I/O circuits 406 and system memory 408. The system memory 408 may further comprise control parameters 420. The CPUs 1 to N are operative to execute one or more applications which reside in system memory 408. The controller 116 may be used to implement any other system, device, element, functionality or method of the embodiments described in the present specification. In the illustrated embodiments, the controller 116 may be configured to implement method 600 (FIG. 4) as processor-executable executable program instructions.

The controller 116 controls the phase difference introduced between the two or more signals coupled to the phase shifter 106 depicted in FIG. 1, where the control parameters 420 contain parameters related to the apparatus 100 considered when modifying the introduced phase difference, or when modifying the timing of the phase difference.

In different embodiments, controller 116 may be any of various types of devices, including, but not limited to, a personal computer system, desktop computer, laptop, notebook, or netbook computer, mainframe computer system, handheld computer, workstation, network computer, a mobile device such as a smart phone or PDA, a consumer device, or in general any type of computing or electronic device.

In various embodiments, controller 116 may be a uniprocessor system including one processor, or a multiprocessor system including several processors (e.g., two, four, eight, or another suitable number). CPUs 1 to N may be any suitable processor capable of executing instructions. For example, in various embodiments CPUs 1 to N may be general-purpose or embedded processors implementing any of a variety of instruction set architectures (ISAs). In multiprocessor systems, each of CPUs 1 to N may commonly, but not necessarily, implement the same ISA.

System memory 408 may be configured to store program instructions and/or data accessible by CPUs 1 to N. In various embodiments, system memory 408 may be implemented using any suitable memory technology, such as static random access memory (SRAM), synchronous dynamic RAM (SDRAM), nonvolatile/Flash-type memory, or any other type of memory. In the illustrated embodiment, program instructions and data implementing any of the elements of the embodiments described above may be stored within system memory 408. In other embodiments, program instructions and/or data may be received, sent or stored upon different types of computer-accessible media or on similar media separate from system memory 408 or controller 116.

In one embodiment, I/O circuits 406 may be configured to coordinate I/O traffic between CPUs 1 to N, system memory 408, and any peripheral devices in the device, including a network interface or other peripheral interfaces, such as input/output devices. In some embodiments, I/O circuits 406 may perform any necessary protocol, timing or other data transformations to convert data signals from one component (e.g., system memory 408) into a format suitable for use by another component (e.g., CPUs 1 to N). In some embodiments, I/O circuits 406 may include support for devices attached through various types of peripheral buses, such as a variant of the Peripheral Component Interconnect (PCI) bus standard or the Universal Serial Bus (USB) standard, for example. In some embodiments, the function of I/O circuits 406 may be split into two or more separate components, such as a north bridge and a south bridge, for example. Also, in some embodiments some or all of the functionality of I/O circuits 406, such as an interface to system memory 408, may be incorporated directly into CPUs 1 to N.

A network interface may be configured to allow data to be exchanged between controller 116 and other devices attached to a network, such as one or more display devices (not shown), or one or more external systems or between nodes. In various embodiments, a network may include one or more networks including but not limited to Local Area Networks (LANs) (e.g., an Ethernet or corporate network), Wide Area Networks (WANs) (e.g., the Internet), wireless data networks, some other electronic data network, or some combination thereof. In various embodiments, the network interface may support communication via wired or wireless general data networks, such as any suitable type of Ethernet network, for example; via telecommunications/telephony networks such as analog voice networks or digital fiber communications networks; via storage area networks such as Fiber Channel SANs, or via any other suitable type of network and/or protocol.

Input/output devices may, in some embodiments, include one or more display terminals, keyboards, keypads, touchpads, scanning devices, voice or optical recognition devices, or any other devices suitable for entering or accessing data by one or more controller 116. Multiple input/output devices may be present or may be distributed on various nodes of controller 116. In some embodiments, similar input/output devices may be separate from controller 116 and may interact with one or more nodes of controller 116 through a wired or wireless connection, such as over a network interface.

In some embodiments, the illustrated controller is an exemplary implementation of methods illustrated by the flowcharts of FIG. 4. In other embodiments, different elements and data may be included.

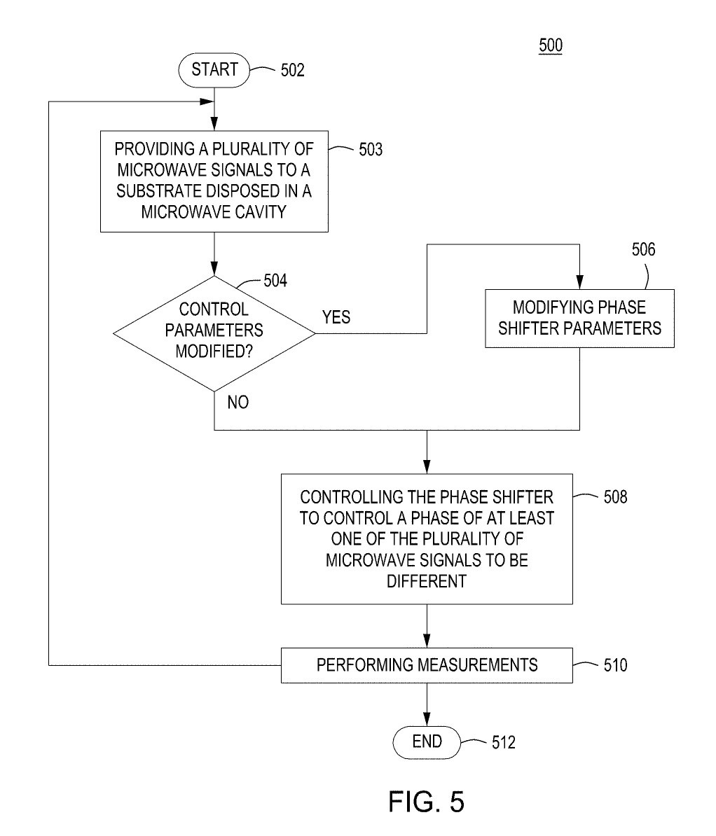

FIG. 5 is a method 500 for processing a substrate with a more uniform thermal distribution in accordance with exemplary embodiments presented herein. The method 500 illustrates the process performed by the controller 116 in achieving uniform thermal distribution across an object being cured or dried in a cavity such as cavity 103 in apparatus 100 by modifying the electric field across the cavity.

The method 500 begins at 502 and proceeds to 504.

At step 503, a plurality of waveguides provides, correspondingly, a plurality of microwave signals to a substrate disposed in a microwave cavity. The microwave signals are generated by a power source such as power source 104 shown in FIG. 1. The substrate is, for example, a semiconductor wafer and the microwave cavity is, for example, one of the chambers used to process the semiconductor wafer in semiconductor processing and packaging.

At 504, the controller 116 determines whether any control parameters have been modified. In some embodiments, the control parameters comprise moisture and electromagnetic field measurements in the cavity, temperature of the object and the cavity or the like. If control parameters have not been modified at 504, the method proceeds to 508. If parameters have been modified, the controller 116 proceeds to 506.

At 506, the parameters of the phase shifter 106 are modified. For example, the control parameters may indicate that the phase angle difference between signals should be greater or lesser. At 506, the controller 116 causes the phase shifter 106 to modify the phase difference parameter.

The method then proceeds to 508 where the controller 116 controls the phase shifter 106 to vary a phase of at least one of the microwave signals to be different than at least one other of the plurality of microwave signals. In some embodiments, the controller 116 varies the phase difference according to the control parameters received by the controller 116. In other embodiments the controller 116 maintains the phase difference between the two or more power signals according to predetermined parameters. As power is fed to a heating apparatus, e.g., apparatus 100, from two or more sources, the signals constructively and destructively interfere creating the electric field patterns shown in FIG. 2. The mixture of non-resonant and evanescent modes induces uniform thermal distribution across wafers for curing and moisture removal in the apparatus 100.

At 510, the controller 116 performs measurements on the apparatus 100 in order to determine if the control parameters require modification again to introduce a differing phase shift in the input power feeds.

The method terminates at 512.

While the foregoing is directed to embodiments of the present disclosure, other and further embodiments of the disclosure may be devised without departing from the basic scope thereof.

1. A microwave oven for semiconductor processing, comprising:
a thermal housing having a cavity and a plurality of input ports;
a power source configured to provide a microwave signal to the cavity of the thermal housing via the plurality of input ports;
a phase shifter disposed between the power source and the input ports, wherein the phase shifter is configured to vary a phase difference between two or more signals provided to it; and
a controller communicatively coupled to the phase shifter and configured to control the phase difference between the two or more signals.

2. The microwave oven of claim 1, further comprising:
a first waveguide that couples the power source to the phase shifter and splits the microwave signal into at least two microwave signals, wherein the at least two microwave signals are input signals for the phase shifter.

3. The microwave oven of claim 2, further comprising:
a second waveguide that couples the phase shifter to a first input port of the plurality of input ports and configured to guide a first microwave signal of the at least two microwave signals into the cavity.

4. The microwave oven of claim 3, further comprising:
a third waveguide that couples the phase shifter to a second input port of the plurality of input ports and configured to guide a second microwave signal of the at least two microwave signals into the cavity,
wherein a phase difference exists between the first microwave signal and the second microwave signal.

5. The microwave oven of claim 4, wherein the first input port and the second input port are disposed in opposing ends of the cavity.

6. The microwave oven of claim 4, further comprising:
a mechanical pedestal with a movable position controlled by the controller.

7. The microwave oven of claim 6, further comprising:
a feedback mechanism coupled to the thermal housing and the controller, wherein the feedback mechanism is configured to determine control parameters, and wherein the controller controls positioning of the mechanical pedestal according to control parameters.

8. The microwave oven of claim 1, further comprising:
a feedback mechanism coupled to the thermal housing and the controller, wherein the feedback mechanism is configured to determine control parameters, and wherein the controller controls the phase difference introduced by the phase shifter according to the control parameters.

9. The microwave oven of claim 1, wherein the controller is configured to control the phase difference introduced by the phase shifter from 0 degrees to 180.

10. The microwave oven of claim 1, wherein the cavity includes a plurality of semiconductor wafers that are suspended therein.

11. The microwave oven of claim 10, wherein the semiconductor wafers are epoxy wafers.

12. The microwave oven of claim 1, wherein the power source is a variable frequency microwave drive.

13. A method for processing a substrate comprising:
providing a plurality of microwave signals to a substrate disposed in a microwave cavity to treat the substrate; and
controlling a phase of at least one of the plurality of microwave signals to be different than at least one other of the plurality of microwave signals.

14. The method of claim 13, further comprising:
measuring control parameters of the substrate and the microwave cavity; and
controlling the phase based on the control parameters.

15. The method of claim 13, wherein the phase difference between the plurality of microwave signals is varied from approximately 0 degrees to 180 degrees.

16. The method of claim 15, further comprising:
measuring control parameters of the substrate and the microwave cavity; and
determining the phase difference based on the control parameters.

17. A microwave oven for uniformly heating semiconductor wafers, comprising:
a thermal housing with a cavity where the semiconductor wafers are suspended;
a phase shifter, coupled to the thermal housing that introduces a phase difference of approximately 0 degrees to 180 degrees between two or more signals;
a power source coupled to the phase shifter that generates a power signal; and
a controller that varies a phase difference between the two or more signals based upon properties of the semiconductor wafers.

18. The microwave oven of claim 17, further comprising:
a first waveguide, coupled to the power source and the phase shifter, that splits the power signal into two signals, wherein the two signals are input signals for the phase shifter.

19. The microwave oven of claim 18, further comprising:
a second waveguide that guides a first signal of the two or more signals into the cavity; and
a third waveguide that guides a second signal of the two or more signals into the cavity, wherein there is a phase difference between the first signal and the second signal.

20. The microwave oven of claim 19, wherein the thermal housing further comprises:
a first input port coupled to the second waveguide; and
a second input port coupled to the third waveguide.
